(19) United States
(12) Patent Application Publication
(10) Pub. No.: US 2026/0371981 A1
(43) Pub. Date: Nov. 19, 2026

(54) CLEANING METHOD, PROCESSING METHOD, AND PROCESSING APPARATUS

(71) Applicant: DISCO CORPORATION, Tokyo (JP)

(72) Inventors: Naoko YAMAMOTO, Tokyo (JP); Yosuke AOYAGI, Tokyo (JP); Yuichi OMURA, Tokyo (JP); Shunsuke TERANISHI, Tokyo (JP); Hirohiko KOZAI, Tokyo (JP); Kenji TAKENOUCHI, Tokyo (JP)

(21) Appl. No.: 19/659,477

(22) Filed: Apr. 27, 2026

(30) Foreign Application Priority Data
May 16, 2025 (JP) 2025-082941

(51) Int. Cl. H10P 70/00; H10P 72/00

(52) U.S. Cl. CPC H10P 70/27; H10P 72/0412

(57) ABSTRACT

A processing method includes: a processing step of processing a workpiece; a first cleaning step of cleaning the workpiece by pressing the workpiece with a first cleaning member under a predetermined load and moving the workpiece and the first cleaning member relative to each other, while supplying a first cleaning solution to the workpiece after the processing step; and a second cleaning step of cleaning the workpiece after the first cleaning step by bringing a second cleaning member into contact with the workpiece and moving the workpiece and the second cleaning member relative to each other, while supplying a second cleaning solution to the workpiece. The predetermined load at the first cleaning step is set to a value greater than a load applied to the workpiece when the second cleaning member comes into contact with the workpiece at the second cleaning step.

### CROSS-REFERENCE TO RELATED APPLICATION(S)

The present application claims priority to and incorporates by reference the entire contents of Japanese Patent Application No. 2025-082941 filed in Japan on May 16, 2025.

### TECHNICAL FIELD

The present disclosure relates to a cleaning method, a processing method, and a processing apparatus.

### BACKGROUND

For example, as devices for cleaning an object to be cleaned, there are widely used a device that cleans an object to be cleaned by bringing a sponge into contact with the object (see, for example, JP 2024-45835 A), a device that cleans a location to be cleaned with a roll member (see, for example, JP 2016-184661 A and JP 2022-35139 A), a spinner cleaning device that cleans an object to be cleaned by ejecting a mixed fluid of liquid and gas to the object (see, for example, JP 2025-14231 A), and the like.

In recent years, along with high integration of semiconductor devices, technique called hybrid bonding for directly bonding semiconductor devices via metal pads instead of bumps has been developed. In hybrid bonding, since the surfaces of metal pads are bonded to each other, bonding failure may occur if foreign matter adheres to the surfaces. Therefore, further removal of foreign matter is desired.

### SUMMARY OF THE INVENTION

A cleaning method according to one aspect of the present disclosure is for cleaning an object to be cleaned. The cleaning method includes: a first cleaning step of cleaning the object by pressing the object with a first cleaning member under a predetermined load and moving the object and the first cleaning member relative to each other, while supplying a first cleaning solution to the object; and a second cleaning step of cleaning the object after the first cleaning step by bringing a second cleaning member into contact with the object and moving the object and the second cleaning member relative to each other, while supplying a second cleaning solution to the object. The predetermined load at the first cleaning step is set to a value greater than a load applied to the object when the second cleaning member comes into contact with the object at the second cleaning step.

A processing method according to another aspect of the present disclosure is for processing a workpiece. The processing method includes: a processing step of processing a workpiece; a first cleaning step of cleaning the workpiece after the processing step by pressing the workpiece with a first cleaning member under a predetermined load and moving the workpiece and the first cleaning member relative to each other, while supplying a first cleaning solution to the workpiece; and a second cleaning step of cleaning the workpiece after the first cleaning step by bringing a second cleaning member into contact with the workpiece and moving the workpiece and the second cleaning member relative to each other, while supplying a second cleaning solution to the workpiece. The predetermined load at the first cleaning step is set to a value greater than a load applied to the workpiece when the second cleaning member comes into contact with the workpiece at the second cleaning step.

A processing apparatus according to still another aspect of the present disclosure includes: a first cleaning solution supply unit that supplies a first cleaning solution to an object to be processed; a first cleaning member that presses the object, to which the first cleaning solution has been supplied, under a predetermined load; a first moving unit that moves the first cleaning member and the object relative to each other to clean the object with the first cleaning member; a second cleaning solution supply unit that supplies a second cleaning solution to the object; a second cleaning member that comes into contact with the object to which the second cleaning solution has been supplied; and a second moving unit that moves the second cleaning member and the object relative to each other to clean the object with the second cleaning member. The predetermined load applied by the first cleaning member is set to a value greater than a load applied to the object when the second cleaning member comes into contact with the object.

### BRIEF DESCRIPTION OF THE DRAWINGS

FIG. 1 is a perspective view schematically illustrating a workpiece to be processed with a processing method according to a first embodiment;

FIG. 2 is a perspective view schematically illustrating a frame unit formed by the workpiece illustrated in FIG. 1;

FIG. 3 is a flowchart illustrating the flow of a processing method according to the first embodiment;

FIG. 4 is a perspective view schematically illustrating a processing step of the processing method illustrated in FIG. 3;

FIG. 5 is a perspective view schematically illustrating a workpiece after the processing step of the processing method illustrated in FIG. 3;

FIG. 6 is a perspective view schematically illustrating a modification of the processing step of the processing method illustrated in FIG. 3;

FIG. 7 is a perspective view schematically illustrating the external appearance of a processing apparatus that performs a cleaning step of the processing method illustrated in FIG. 3;

FIG. 8 is a horizontal cross-sectional view of the processing apparatus illustrated in FIG. 7;

FIG. 9 is a vertical cross-sectional view of the processing apparatus illustrated in FIG. 7;

FIG. 10 is a side view schematically illustrating the configuration of a first cleaning unit of the processing apparatus illustrated in FIG. 7 in a partial cross section;

FIG. 11 is a side view schematically illustrating a first cleaning member cleaner of the first cleaning unit illustrated in FIG. 10 in a partial cross section;

FIG. 12 is a side view schematically illustrating the configuration of a second cleaning unit of the processing apparatus illustrated in FIG. 7 in a partial cross section;

FIG. 13 is a side view schematically illustrating, in a partial cross section, a state in which the workpiece is cleaned by supplying a first cleaning solution at a first cleaning step of the processing method illustrated in FIG. 3;

FIG. 14 is a side view schematically illustrating, in a partial cross section, a state in which the workpiece is cleaned by supplying a third cleaning solution at the first cleaning step of the processing method illustrated in FIG. 3;

FIG. 15 is a side view schematically illustrating, in a partial cross section, a first rinsing step of the processing method illustrated in FIG. 3;

FIG. 16 is a side view schematically illustrating a second cleaning step of the processing method illustrated in FIG. 3 in a partial cross section;

FIG. 17 is a side view schematically illustrating, in a partial cross section, a rinsing step of the processing method illustrated in FIG. 3; and

FIG. 18 is a side view schematically illustrating, in a partial cross section, a drying step of the processing method illustrated in FIG. 3.

### DETAILED DESCRIPTION OF THE PREFERRED EMBODIMENTS

Embodiments of the present disclosure will be described in detail with reference to the drawings. The present invention is not limited by the content described in the following embodiments. In addition, the components described below include those that can be easily conceived of by those skilled in the art and those that are substantially the same. Furthermore, the configurations described below can be combined as appropriate. In addition, various omissions, substitutions, or modifications of the configurations can be made without departing from the gist of the present invention.

### First Embodiment

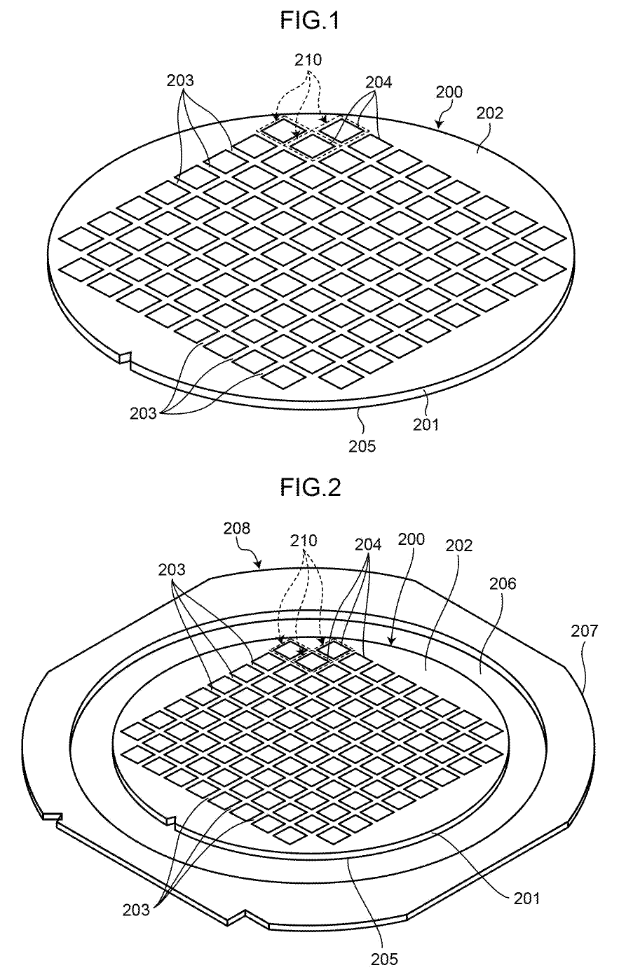

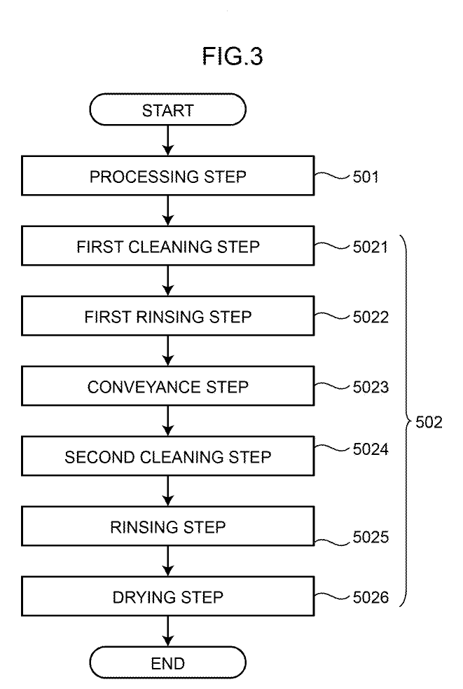

A processing method according to a first embodiment of the present invention will be described with reference to the drawings. FIG. 1 is a perspective view schematically illustrating a workpiece to be processed by a processing method according to the first embodiment. FIG. 2 is a perspective view schematically illustrating a frame unit formed by the workpiece illustrated in FIG. 1. FIG. 3 is a flowchart illustrating the flow of the processing method according to the first embodiment.

### Workpiece

The processing method according to the first embodiment is a method of processing a workpiece 200 (corresponding to an object to be cleaned and an object to be processed) illustrated in FIG. 1. The workpiece 200 to be processed with the processing method according to the first embodiment is a wafer such as a disk-shaped semiconductor device wafer or an optical device wafer using silicon, gallium arsenide, silicon carbide (SiC), sapphire, or the like as a substrate 201. As illustrated in FIG. 1, in the workpiece 200, devices 204 are formed in regions partitioned by a plurality of planned division lines 203 formed in a lattice shape on a front surface 202 (corresponding to a surface to be cleaned).

The device 204 is, for example, an integrated circuit such as an integrated circuit (IC) or a large scale integration (LSI), a light-emitting diode (LED), an image sensor such as a charge coupled device (CCD) or a complementary metal oxide semiconductor (CMOS), a micro electro mechanical systems (MEMS), or various memories (semiconductor storage devices).

In the first embodiment, the devices 204 of the workpiece 200 are semiconductor devices in which metal connection pads are formed on the front side, and the workpiece 200 is a semiconductor device wafer. In the first embodiment, as illustrated in FIG. 2, a central portion of a disk-shaped tape 206 having a diameter larger than that of the workpiece 200 is attached to a back surface 205 of the workpiece 200 that is on the back side of the front surface 202, and a ring-shaped frame 207 is attached to the outer periphery of the tape 206, whereby the workpiece 200 is supported by the frame 207 to form a frame unit 208 (corresponding to an object to be processed).

In the first embodiment, the workpiece 200 is fixed onto the tape 206, and the outer periphery of the tape 206 is fixed to the frame 207, thereby forming the frame unit 208. In the first embodiment, the processing method is performed while the workpiece 200 is fixed onto the tape 206, and the outer periphery of the tape 206 is fixed to the frame 207, and the workpiece 200 is divided into individual semiconductor device chips 210. The semiconductor device chips 210 each includes a portion of the substrate 201 and a device 204.

### Processing Method

The processing method according to the first embodiment is a method of processing the workpiece 200. The processing method according to the first embodiment is also a method for manufacturing a plurality of semiconductor device chips 210 by dividing the workpiece 200 along planned division lines 203, the workpiece 200 being a semiconductor device wafer including the front surface 202 on which devices 204, which are individual semiconductor devices, are formed in respective regions partitioned by the planned division lines 203. As illustrated in FIG. 3, the processing method according to the first embodiment includes a processing step 501 and a cleaning step 502.

### Processing Step

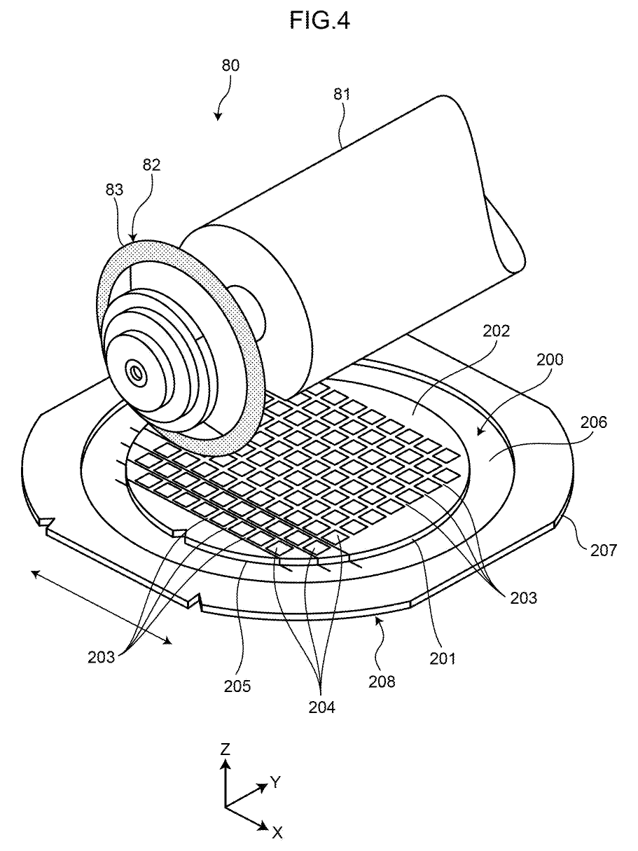

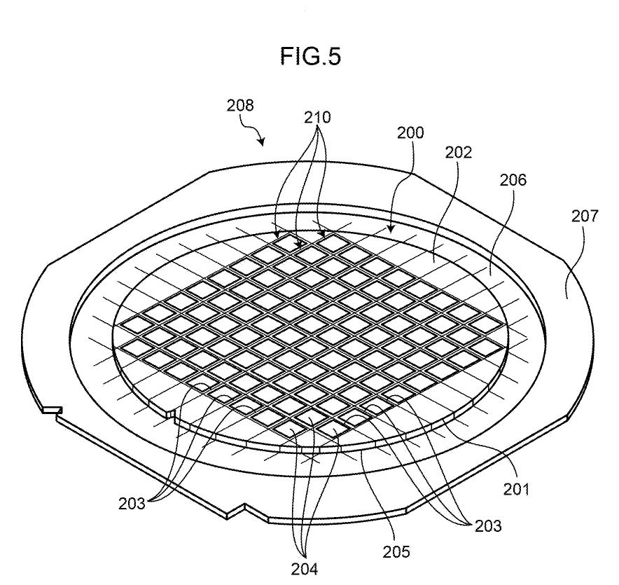

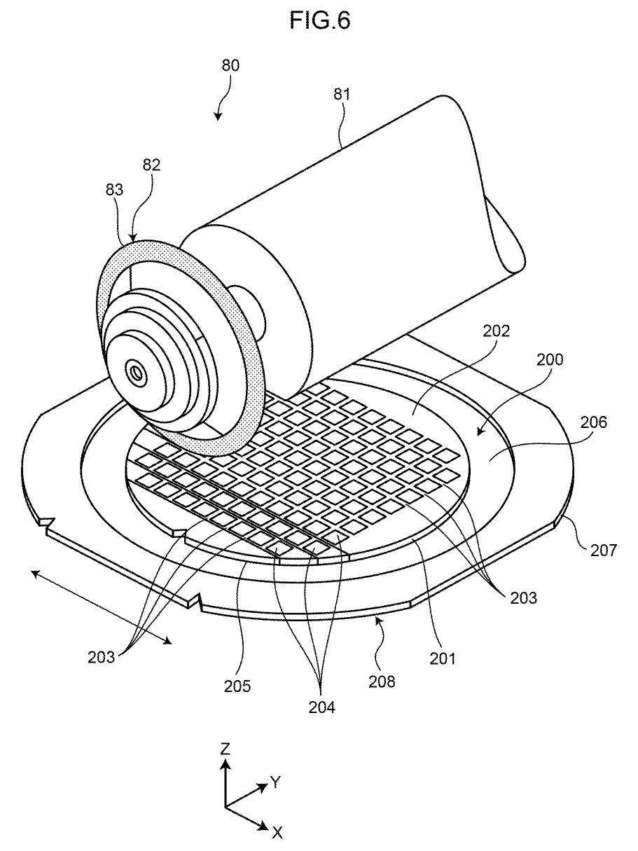

FIG. 4 is a perspective view schematically illustrating the processing step of the processing method illustrated in FIG. 3. FIG. 5 is a perspective view schematically illustrating a workpiece after the processing step of the processing method illustrated in FIG. 3. FIG. 6 is a perspective view schematically illustrating a modification of the processing step of the processing method illustrated in FIG. 3. The processing step 501 is a step of processing the workpiece 200.

In the first embodiment, at the processing step 501, a processing device 80 illustrated in FIG. 4 holds the workpiece 200 on a holding table (not illustrated) of the processing device 80 while holding the workpiece 200 on the frame 207 by the tape 206, and clamps the frame 207 with a clamp unit (not illustrated). In the first embodiment, at the working step 501, the processing device 80 captures an image of the workpiece 200 with an imaging unit (not illustrated), and performs alignment for aligning a cutting blade 82 of a cutting unit 81 and the planned division lines 203 of the workpiece 200.

In the first embodiment, at the working step 501, as illustrated in FIG. 4, the processing device 80 cuts the planned division lines 203 by cutting the workpiece 200 along the planned division lines 203 with an edge 83 of the cutting blade 82 until the edge 83 of the cutting blade 82 reaches the tape 206 while moving the cutting blade 82 and the workpiece 200 relative to each other along the planned division lines 203. In the first embodiment, at the working step 501, the processing device 80 cuts all the planned division lines 203 with the cutting blade 82 to divide the workpiece 200 into individual semiconductor device chips 210 as illustrated in FIG. 5.

In this manner, in the first embodiment, at working step 501, the workpiece 200 is divided into pieces along the planned division lines 203. That is, in the first embodiment, the working step 501 is a dividing step of cutting the workpiece 200, which is a semiconductor device wafer, along the planned division lines 203 with the cutting blade 82 to divide the workpiece 200 along the planned division lines 203 to form the semiconductor device chips 210.

In the present invention, at the working step 501, the workpiece 200 as a semiconductor device wafer may be divided by laser dicing or plasma dicing in addition to division by cutting. Furthermore, in the present invention, at the working step 501, as illustrated in FIG. 6, the processing device 80 may divide the workpiece 200 which is a semiconductor device wafer by forming cutting grooves from the front surface 202 side along the planned division lines 203 by allowing the edge 83 of the cutting blade 82 to enter the center of the workpiece 200 in the thickness direction without reaching the tape 206, and then grinding the back surface 205. Instead of the cutting grooves, laser working grooves may be formed.

In the present invention, at the working step 501, a modified layer along the planned division lines 203 may be formed by irradiating the front surface 202 or the back surface 205 of the workpiece 200, which is a semiconductor device wafer, with a laser beam along the planned division lines 203, and then the workpiece 200 may be divided by grinding the back surface 205 to form the semiconductor device chips 210. After the workpiece 200 is divided by grinding from the back surface 205, the frame unit 208 may be formed by fixing the back surface 205 of the divided workpiece 200 to the tape 206 and fixing the outer peripheral edge of the tape 206 to the frame 207.

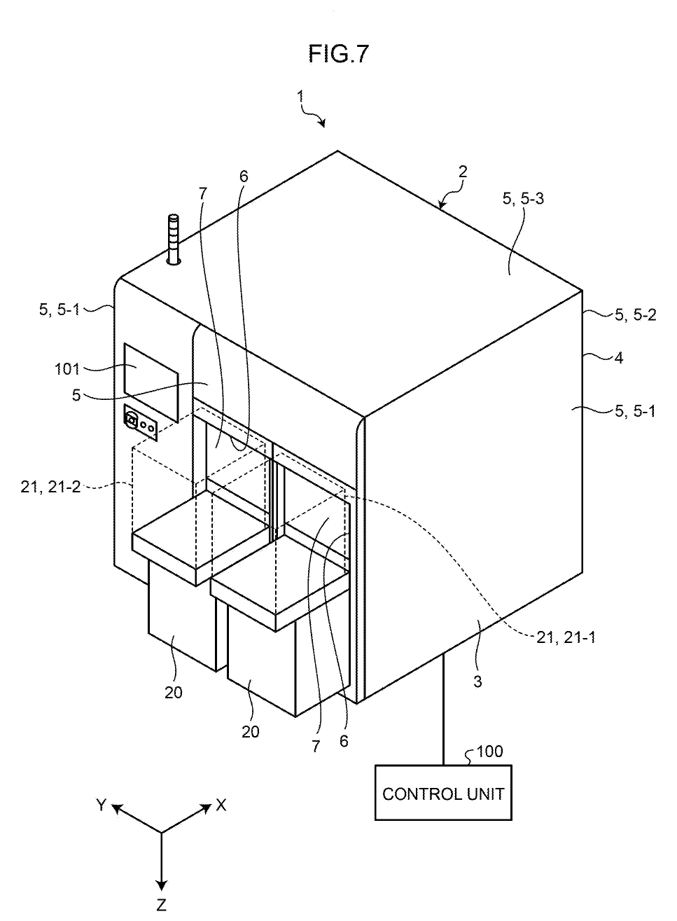

The cleaning step 502 is a step of cleaning the workpiece 200 after the working step 501. The cleaning step 502 according to the first embodiment is performed by a processing device 1 illustrated in FIG. 7. Next, the processing apparatus 1 will be described with reference to the drawings.

### Processing Apparatus

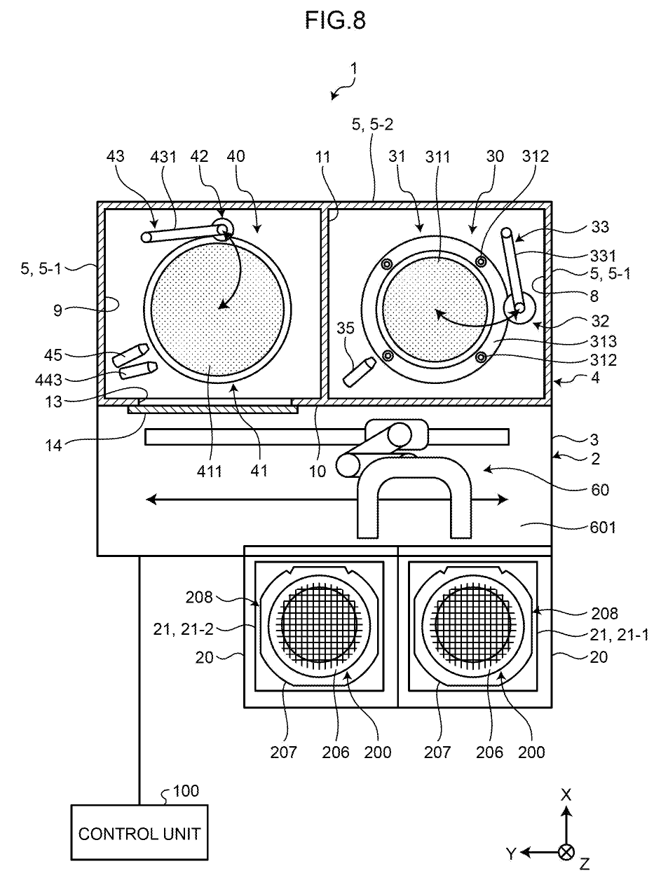

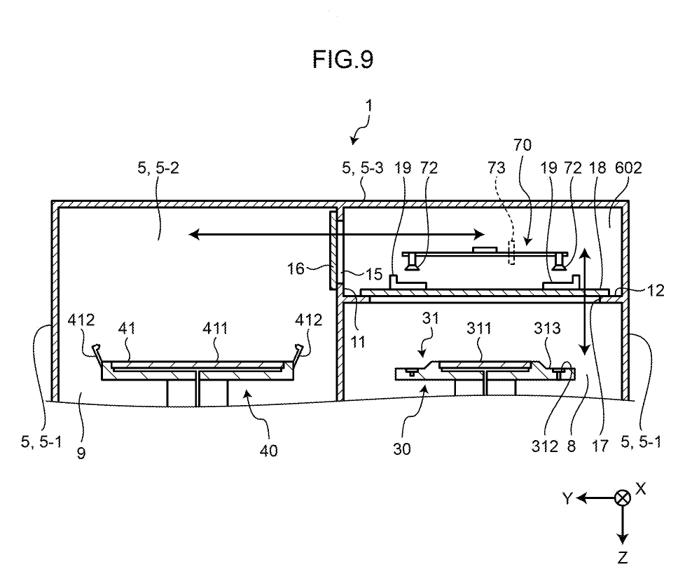

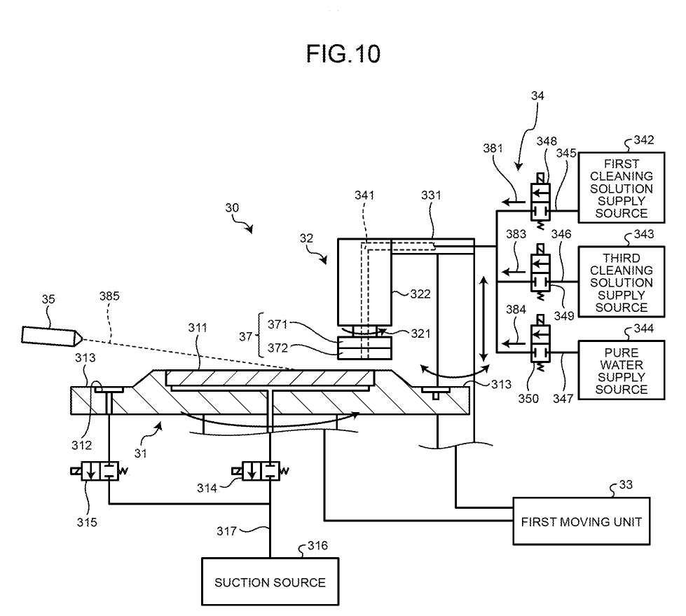

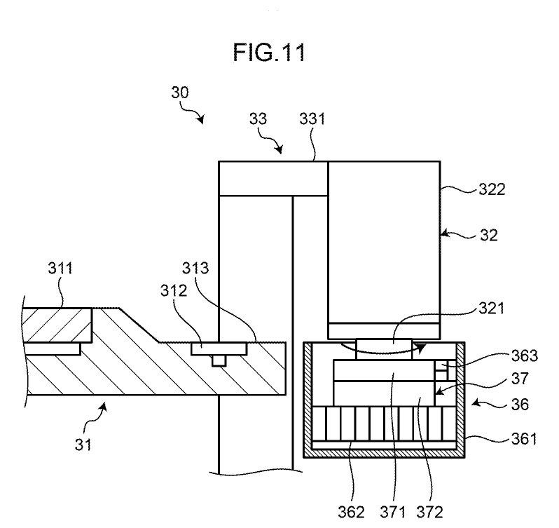

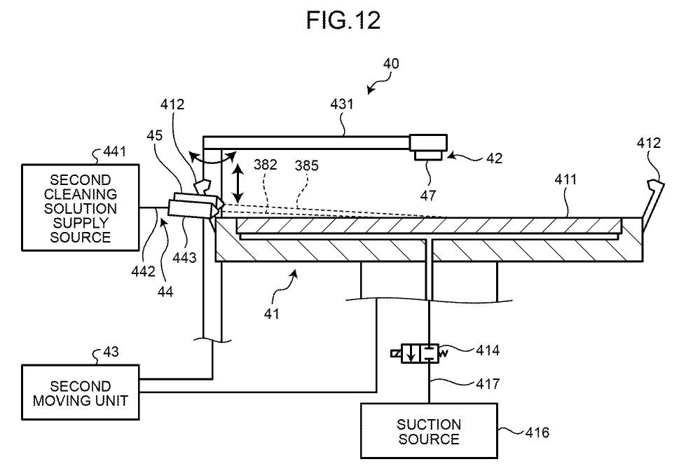

FIG. 7 is a perspective view schematically illustrating the external appearance of the processing apparatus that performs the cleaning step of the processing method illustrated in FIG. 3. FIG. 8 is a horizontal cross-sectional view of the processing apparatus illustrated in FIG. 7. FIG. 9 is a vertical cross-sectional view of the processing apparatus illustrated in FIG. 7. FIG. 10 is a side view schematically illustrating the configuration of a first cleaning unit of the processing apparatus illustrated in FIG. 7 in a partial cross section. FIG. 11 is a side view schematically illustrating a first cleaning member cleaner of the first cleaning unit illustrated in FIG. 10 in a partial cross section. FIG. 12 is a side view schematically illustrating the configuration of a second cleaning unit of the processing apparatus illustrated in FIG. 7 in a partial cross section.

The processing apparatus 1 is an apparatus which cleans the front surface 202 of the workpiece 200 of the frame unit 208. In the first embodiment, as illustrated in FIGS. 7 and 8, the processing apparatus 1 includes a housing 2, cassette placing tables 20, a first cleaning unit 30 (illustrated in FIG. 8), a second cleaning unit 40 (illustrated in FIG. 8), a loading/unloading unit 60, a conveyance unit 70 illustrated in FIG. 9, and a control unit 100.

The housing 2 constitutes the external appearance of the processing apparatus 1. The housing 2 includes an apparatus base 3 (illustrated in FIG. 8) placed on a floor of a factory or the like, and a chamber 4 covering the apparatus base 3 from above. The chamber 4 includes a plurality of plate members 5 each having a flat plate shape. A plate member 5 on the front side in FIG. 7 among the plate members 5 of the chamber 4 is provided with openings 6 through which the workpiece 200 can be taken in and out, and shutters 7 that open and close the openings 6. In the first embodiment, two openings 6 are provided spaced apart from each other in the Y axis direction that is parallel to the horizontal direction.

As illustrated in FIG. 8, a first cleaning chamber 8 and a second cleaning chamber 9 are provided at one end of the chamber 4 of the housing 2 in the X axis direction parallel to the horizontal direction and orthogonal to the Y axis direction. The first cleaning chamber 8 accommodates a first cleaning member 37, described later, and is capable of accommodating the frame unit 208. The second cleaning chamber 9 accommodates a second cleaning member 47, described later, and is capable of accommodating a frame unit 208.

The cleaning chambers 8 and 9 are spaces partitioned from each other in the chamber 4, and are spaces covered by: a common partition wall 10 illustrated in FIG. 8; plate members 5 (hereinafter, indicated by reference numeral 5-1) illustrated in FIGS. 8 and 9, which are provided at both ends in the Y axis direction, separated from each other, and constitutes the external appearance of the chamber 4; a common plate member 5 (hereinafter, indicated by reference numeral 5-2) illustrated in FIGS. 8 and 9, which is provided at one end in the X axis direction of the chamber 4; a partition plate 11 illustrated in FIGS. 8 and 9; and a middle plate 12 illustrated in FIG. 9.

The partition wall 10 is erected from the center of the apparatus base 3 in the X axis direction, and has a surface formed in a flat plate shape parallel to the Y axis direction and the Z axis direction. The outer edge of the partition wall 10 is continuous with the plate members 5-1 and the plate member 5 (hereinafter, indicated by reference numeral 5-3) illustrated in FIG. 7 and constituting the ceiling of the external appearance of the chamber 4. The partition wall 10 has an opening (not illustrated) through which the workpiece 200 can be accommodated above the middle plate 12 and has an opening 13 that allows the workpiece 200 to be unloaded from the second cleaning chamber 9, and the opening 13 is opened and closed by a shutter 14.

The partition plate 11 partitions the first cleaning chamber 8 and the second cleaning chamber 9. The partition plate 11 is erected from one end of the apparatus base 3 in the X axis direction and from the center in the Y axis direction, and is formed to have a surface having a flat plate shape parallel to the X axis direction and the Z axis direction. The partition plate 11 has the outer edge continuous with the partition wall 10 and the plate members 5-2 and 5-3. Furthermore, the partition plate 11 is provided with an opening 15 that allows the workpiece 200 to move to the second cleaning chamber 9 from above the middle plate 12, and the opening 15 is opened and closed by a shutter 16.

The middle plate 12 has a surface formed in a flat plate shape parallel to the X axis direction and the Y axis direction, and has the outer edge continuous with the partition wall 10, the partition plate 11, and the plate members 5-1 and 5-2, and is disposed in the upper part of the first cleaning chamber 8. The middle plate 12 is disposed between the apparatus base 3 and the plate member 5-3.

As illustrated in FIG. 9, an opening 17 through which the workpiece 200 can be taken in and out is provided on the first cleaning chamber 8 side of the middle plate 12, and the opening 17 is opened and closed by a shutter 18. The shutter 18 is provided with a pair of positioning members 19 that comes into contact with the outer edge of the frame 207 supporting the workpiece 200 on the upper surface side to position the frame 207, namely, the workpiece 200.

The cassette placing tables 20 are provided at the other end of the apparatus base 3 of the housing 2 in the X axis direction. In the first embodiment, two cassette placing tables are provided spaced apart from each other in the Y axis direction. A cassette 21 for accommodating the workpiece 200 before and after cleaning is placed on a cassette placing table 20. The cassette 21 is a storage container that stores a plurality of workpieces 200 at intervals in the Z axis direction, and allows the workpieces 200 to be taken in and out through an opening.

On the cassette placing table 20, the cassette 21 is placed in a state where the opening of the cassette 21, through which the workpieces 200 can be taken in and out, faces the opening 6 of the chamber 4. In the first embodiment, among the cassettes 21 placed on the two cassette placing tables 20, one cassette 21 on the right side in FIG. 7 (hereinafter, referred to as a first cassette 21-1) accommodates workpieces 200 before cleaning, and the other cassette 21 on the left side in FIG. 7 (hereinafter, referred to as a second cassette 21-2) accommodates workpieces 200 after cleaning.

The first cleaning unit 30 and the second cleaning unit 40 are units for cleaning the front surface 202 of the workpiece 200 of the frame unit 208. As illustrated in FIG. 9, the first cleaning unit 30 is accommodated in the first cleaning chamber 8. As illustrated in FIG. 10, the first cleaning unit 30 includes a first spinner table 31, a first surface cleaning unit 32, a first moving unit 33, a first cleaning solution supply unit 34, a first rinse water supply nozzle 35, and a first cleaning member cleaner 36 illustrated in FIG. 11.

The first spinner table 31 includes: a holding surface 311 formed in a disk shape, provided at the center, and made of a porous material such as porous ceramics; and a frame suction unit 313 provided at the outer edge, positioned lower than the holding surface 311 in the Z axis direction, and having a suction hole 312 opened. The back surface 205 of the workpiece 200 is placed on the holding surface 311 via the tape 206 of the frame unit 208. The frame 207 of the frame unit 208 is placed on the frame suction unit 313.

As illustrated in FIG. 10, the holding surface 311 and the suction hole 312 are connected to a suction channel 317 connected to a suction source 316 through valves 314 and 315. The on-off valves 314 and 315 are opened and the holding surface 311 and the suction hole 312 are sucked by the suction source 316, whereby the first spinner table 31 sucks and holds the workpiece 200 and the frame 207 placed on the holding surface 311 and the frame suction unit 313. The first spinner table 31 is rotated about an axis parallel to the Z axis direction by the first moving unit 33.

The first surface cleaning unit 32 cleans the front surface 202 of the workpiece 200 held on the first spinner table 31. The first surface cleaning unit 32 includes: a cylindrical spindle 321 whose axis is parallel to the Z axis direction; a spindle housing 322 that accommodates the spindle 321 in a state where a lower end of the spindle 321 is exposed; and a first cleaning member 37 attached to the lower end of the spindle 321. The spindle housing 322 accommodates the spindle 321 such that the spindle 321 is rotatable about its axis.

Since the first cleaning member 37 is attached to the lower end of the spindle 321, the first cleaning member 37 is disposed in the first cleaning chamber 8. The first cleaning member 37 is formed in a thick disk shape, comes in contact with the front surface 202 of the workpiece 200 to press the workpiece 200 under a predetermined load, and cleans at least the front surface 202 of the workpiece 200 of the frame unit 208. In the first embodiment, the outer diameter of the first cleaning member 37 is preferably smaller than the outer diameter of the workpiece 200. With the outer diameter of the first cleaning member 37 being smaller than that of the workpiece 200, it is possible to locally change the cleaning state depending on the situation where foreign matter adheres to the front surface 202 of the workpiece 200 by locally changing the time or load for cleaning such as additionally cleaning a local area during cleaning of the entire front surface 202 or before cleaning the entire front surface 202 after cleaning the entire front surface 202 of the workpiece 200 or locally changing the load.

In the first embodiment, the outer diameter of the first cleaning member 37 is more preferably equal to or less than the radius of the workpiece 200, and is preferably formed to be larger than the size covering at least one semiconductor device chip 210. This is to prevent, when cleaning the workpiece 200 in which at least one semiconductor device chip 210 has fallen off the tape 206, the first cleaning member 37 from falling into the area where the semiconductor device chip 210 has fallen off during cleaning.

In the first embodiment, the outer diameter of the first cleaning member 37 is, for example, 100 mm. The first cleaning member 37 includes: a platen 371 attached to the lower end of the spindle 321 and made of metal such as stainless steel; and a polishing pad 372 attached to the lower surface of the platen 371, capable of coming into contact with the workpiece 200, and made of, for example, nonwoven fabric. The lower surface of the polishing pad 372 is a pressing surface that presses the front surface 202 of the workpiece 200 and has an outer diameter smaller than that of the workpiece 200.

The first moving unit 33 moves the first cleaning member 37 and the workpiece 200 relative to each other to clean the workpiece 200 with the first cleaning member 37. The first moving unit 33 includes: an arm 331 that supports the spindle housing 322 of the first surface cleaning unit 32 at its distal end and has its proximal end disposed on the outer periphery of the first spinner table 31; a rotation drive source (not illustrated) to rotate the first spinner table 31 about its axis; a swing drive source (not illustrated) to swing the arm 331 about its proximal end; a lifting drive source (not illustrated) to lift and lower the arm 331 in the Z axis direction; and a spindle rotation drive source to rotate the spindle 321 about its axis. In the first embodiment, the length of the arm 331 in the horizontal direction is, for example, 400 mm.

The first moving unit 33 rotates the first spinner table 31 holding the workpiece 200 about its axis, lowers the arm 331 in a state where the spindle 321, namely, the first cleaning member 37 is rotated about its axis, and in a state where the front surface 202 of the workpiece 200 is pressed with the polishing pad 372 of the first cleaning member 37 under a predetermined load, the swing drive source swings the arm 331 to clean the front surface 202 of the workpiece 200 by the polishing pad 372 of the first cleaning member 37. At this point, the first cleaning member 37 passes over the center of the workpiece 200 held on the first spinner table 31.

The first cleaning solution supply unit 34 supplies at least a first cleaning solution 381 to at least the front surface 202 of the workpiece 200 held on the first spinner table 31 of the frame unit 208. The first cleaning solution supply unit 34 includes a first supply channel 341, a first cleaning solution supply source 342, a third cleaning solution supply source 343, a pure water supply source 344, a first cleaning solution supply channel 345, a third cleaning solution supply channel 346, and a pure water supply channel 347.

The first supply channel 341 is a channel provided in the arm 331, the spindle 321, and the like and opened to the lower surface of the polishing pad 372. The first cleaning solution supply source 342 supplies the first cleaning solution 381. In the first embodiment, the first cleaning solution 381 is, for example, at least one of slurry containing abrasive or a polishing solution containing no abrasive.

The third cleaning solution supply source 343 supplies a third cleaning solution 383. In the first embodiment, the third cleaning solution 383 is, for example, a polishing solution containing no abrasive. In the first embodiment, the slurry containing abrasive and the polishing solution not containing abrasive, which are the first cleaning solution 381 or the third cleaning solution 383, include, for example, an acidic or alkaline aqueous solution, and may contain a complexing material, a corrosion inhibitor, a pH adjusting agent, and the like.

The pure water supply source 344 supplies pure water 384. In the first embodiment, the pure water 384 may be added with carbon dioxide or ammonia as a countermeasure against static electricity, or may not be added with carbon dioxide or ammonia. In a case where carbon dioxide or ammonia is added, the pure water 384 is alkaline water having a low concentration within a range of about 1 ppm to 5 ppm in which an alkaline solution is mixed in pure water, or carbon dioxide water in which carbon dioxide is mixed in pure water.

The first cleaning solution supply channel 345 is a path connecting the first cleaning solution supply source 342 and the first supply channel 341, and supplies the first cleaning solution 381 from the first cleaning solution supply source 342 to the lower surface of the polishing pad 372 through the first supply channel 341. The first cleaning solution supply channel 345 is provided with an on-off valve 348.

The third cleaning solution supply channel 346 is a path connecting the third cleaning solution supply source 343 and the first supply channel 341, and supplies the third cleaning solution 383 from the third cleaning solution supply source 343 to the lower surface of the polishing pad 372 through the first supply channel 341. The third cleaning solution supply channel 346 is provided with an on-off valve 349.

The pure water supply channel 347 is a path connecting the pure water supply source 344 and the first supply channel 341, and supplies the pure water 384 from the pure water supply source 344 to the lower surface of the polishing pad 372 through the first supply channel 341. The pure water supply channel 347 is provided with an on-off valve 350.

In response to opening or closing of the on-off valves 348, 349, and 350, the first cleaning solution supply unit 34 supplies any one of the first cleaning solution 381, the third cleaning solution 383, or the pure water 384 to the front surface 202 of the workpiece 200 held on the first spinner table 31 via the lower surface of the polishing pad 372.

The first rinse water supply nozzle 35 is fixed to the outer peripheral side of the first spinner table 31. The first rinse water supply nozzle 35 ejects a rinse water 385 supplied from a rinse water supply source (not illustrated) toward the front surface 202 of the workpiece 200 held on the first spinner table 31. In the first embodiment, the rinse water 385 ejected from the first rinse water supply nozzle 35 lands on the center of the holding surface 311 of the first spinner table 31.

The first cleaning member cleaner 36 cleans the first cleaning member 37. The first cleaning member cleaner 36 is fixed to the outside of the first spinner table 31, and is disposed on the movement locus of the first cleaning member 37 when the arm 331 swings. As illustrated in FIG. 11, the first cleaning member cleaner 36 includes: a cleaner body 361 formed in a cylindrical shape with the upper side opened and the lower side closed and capable of accommodating the first cleaning member 37; a polishing surface cleaning brush 362 provided at the bottom of the cleaner body 361; and a side surface cleaning brush 363 provided on the inner peripheral surface of the cleaner body 361.

The polishing surface cleaning brush 362 comes into contact with the lower surface of the polishing pad 372 of the first cleaning member 37 in the cleaner body 361 to clean the lower surface of the polishing pad 372. The side surface cleaning brush 363 comes into contact with the outer peripheral surface of the platen 371 of the first cleaning member 37 in the cleaner body 361 to clean the outer peripheral surface of the platen 371. The polishing surface cleaning brush 362 and the side surface cleaning brush 363 are made of, for example, polyamide, polypropylene, polyethylene, polyester, or the like.

The first cleaning member cleaner 36 accommodates the first cleaning member 37 in the cleaner body 361, fills the cleaner body 361 with pure water 384 supplied from the pure water supply source 344, brings the lower surface of the polishing pad 372 into contact with the polishing surface cleaning brush 362, and brings the outer peripheral surface of the platen 371 into contact with the side surface cleaning brush 363. The first cleaning member cleaner 36 rotates the spindle 321 and the first cleaning member 37 about the axis thereof by the spindle rotation drive source to clean the lower surface of the polishing pad 372 and the outer peripheral surface of the platen 371.

As illustrated in FIG. 9, the second cleaning unit 40 is accommodated in the second cleaning chamber 9. As illustrated in FIG. 12, the second cleaning unit 40 includes a second spinner table 41, a second surface cleaning unit 42, a second moving unit 43, a second cleaning solution supply unit 44, and a second rinse water supply nozzle 45.

The second spinner table 41 is formed in a disk shape and has a flat circular upper surface. The second spinner table 41 includes: a holding surface 411 provided at the center of the upper surface and made of a porous material such as porous ceramics; and a frame holder 412 that holds the frame 207 and is provided at the outer edge. The back surface 205 of the workpiece 200 is placed on the holding surface 411 via the tape 206 of the frame unit 208.

A suction channel 417 provided with an on-off valve 414 and connected to a suction source 416 is connected to the holding surface 411. The on-off valve 414 is opened and the holding surface 411 is sucked by the suction source 416, whereby the second spinner table 41 sucks and holds the workpiece 200 placed on the holding surface 411. The second spinner table 41 is rotated about its axis parallel to the Z axis direction by the second moving unit 43. When the second spinner table 41 is rotated about its axis by the second moving unit 43, a frame holder 412 holds the frame 207 by centrifugal force. As described above, in the first embodiment, the frame holder 412 of the second spinner table 41 is a pendulum-type frame holder.

The second surface cleaning unit 42 cleans the front surface 202 of the workpiece 200 held on the second spinner table 41. The second surface cleaning unit 42 includes a disk-shaped second cleaning member 47. The second cleaning member 47 comes into contact with the front surface 202 of the workpiece 200 to clean at least the front surface 202 of the workpiece 200 of the frame unit 208. In the first embodiment, the outer diameter of the second cleaning member 47 is smaller than the outer diameter of the workpiece 200 and the outer diameter of the first cleaning member 37, and is, for example, 20 mm. The second cleaning member 47 is made of, for example, urethane. The lower surface of the second cleaning member 47 is a contact surface having an outer diameter smaller than that of the workpiece 200 coming into contact with the front surface 202 of the workpiece 200.

The second moving unit 43 moves the second cleaning member 47 and the workpiece 200 relative to each other to clean the workpiece 200 with the first cleaning member 37. The second moving unit 43 includes: an arm 431 that supports the second cleaning member 47 at its distal end and has its proximal end disposed on the outer periphery of the second spinner table 41; a rotation drive source (not illustrated) to rotate the second spinner table 41 about its axis; a swing drive source (not illustrated) to swing the arm 431 about its proximal end; and a lifting drive source (not illustrated) to lift and lower the arm 431 in the Z axis direction.

In the first embodiment, the length of the arm 431 is 400 mm. Since the arm 431 supports the second cleaning member 47 at its distal end, the second cleaning member 47 is disposed in the second cleaning chamber 9.

The second moving unit 43 rotates the second spinner table 41 holding the workpiece 200 about its axis, and in a state where the arm 431 is lowered to bring the second cleaning member 47 into contact with the front surface 202 of the workpiece 200, the swing drive source swings the arm 431 to clean the front surface 202 of the workpiece 200 by the second cleaning member 47. At this point, the second cleaning member 47 passes over the center of the workpiece 200 held on the second spinner table 41.

The second cleaning solution supply unit 44 supplies a second cleaning solution 382 to at least the front surface 202 of the workpiece 200 held on the second spinner table 41 of the frame unit 208. The second cleaning solution supply unit 44 includes a second cleaning solution supply source 441, a second cleaning solution supply channel 442, and a second cleaning solution supply nozzle 443.

The second cleaning solution supply source 441 supplies the second cleaning solution 382. In the first embodiment, the second cleaning solution 382 is, for example, an acidic or alkaline aqueous solution.

The second cleaning solution supply channel 442 is a channel connecting the second cleaning solution supply source 441 and the second cleaning solution supply nozzle 443, and supplies the second cleaning solution 382 from the second cleaning solution supply source 441 to the front surface 202 of the workpiece 200 held on the second spinner table 41 via the second cleaning solution supply nozzle 443. The second cleaning solution supply channel 442 is provided with an on-off valve (not illustrated).

The second cleaning solution supply nozzle 443 is fixed to the outer peripheral side of the second spinner table 41. The second cleaning solution supply nozzle 443 ejects the second cleaning solution 382 supplied from the second cleaning solution supply source 441 toward the front surface 202 of the workpiece 200 held on the second spinner table 41. In the first embodiment, the second cleaning solution 382 ejected from the second cleaning solution supply nozzle 443 lands on the center of the holding surface 411 of the second spinner table 41 and at a position avoiding the movement locus of the second cleaning member 47 when the arm 431 swings.

The second cleaning solution supply unit 44 supplies the second cleaning solution 382 to the front surface 202 of the workpiece 200 held on the second spinner table 41 with the on-off valve opened.

The second rinse water supply nozzle 45 is fixed to the outer peripheral side of the second spinner table 41. The second rinse water supply nozzle 45 ejects the rinse water 385 supplied from a rinse water supply source (not illustrated) toward the front surface 202 of the workpiece 200 held on the second spinner table 41. In the first embodiment, the rinse water 385 ejected from the second rinse water supply nozzle 45 lands on the center of the holding surface 411 of the second spinner table 41.

In the first embodiment, the rinse water 385 supplied by each of the rinse water supply nozzles 35 and 45 is pure water or pure water to which carbon dioxide or ammonia is added as a countermeasure against static electricity.

The loading/unloading unit 60 is placed in the chamber 4 and on the apparatus base 3, and is provided between the cassette placing tables 20 and the cleaning chambers 8 and 9 as illustrated in FIG. 8. The loading/unloading unit 60 takes out one workpiece 200 before cleaning from the first cassette 21-1, and conveys the workpiece 200 through an opening onto the positioning members 19 with the opening 17 closed. The loading/unloading unit 60 conveys the workpiece 200 on the second spinner table 41 after cleaning into the second cassette 21-2. The loading/unloading unit 60 is, for example, a robot pick including a U-shaped hand, and sucks, holds, and conveys the workpiece 200 by the U-shaped hand.

The conveyance unit 70 conveys the frame unit 208 from the positioning members 19 to the first cleaning chamber 8, and conveys the frame unit 208 from the first cleaning chamber 8 to the second cleaning chamber 9. The conveyance unit 70 is disposed above the spinner tables 31 and 41 in the chamber 4, and is provided so as to be movable in the X axis direction and the Z axis direction in the chamber 4. The conveyance unit 70 sucks and holds the frame 207 supporting the workpiece 200 on the positioning members 19 provided to the shutter 18 with the opening 17 closed, and places the workpiece 200 on the holding surface 311 of the first spinner table 31.

The conveyance unit 70 sucks and holds the frame 207 supporting the workpiece 200 cleaned by the first cleaning unit 30, and places the workpiece 200 on the holding surface 411 of the second spinner table 41. As illustrated in FIG. 9, the conveyance unit 70 includes a thin unit body 71 and a plurality of suction holders 72 (corresponding to holders) that suck and hold the frame 207 of the frame unit 208, the suction holders 72 provided on the outer edge of the unit body 71. The conveyance unit 70 may also include a rinse water supply unit 73 indicated by a broken line in FIG. 9 that supplies the above-described rinse water 385 to the front surface 202 of the workpiece 200 supported by the frame 207 sucked and held by the suction holders 72.

The control unit 100 controls each of the above-described components constituting the processing apparatus 1. That is, the control unit 100 causes the processing apparatus 1 to execute the cleaning operation on the workpiece 200. The control unit 100 is a computer capable of executing a computer program, the computer including an arithmetic processing device having a microprocessor such as a central processing unit (CPU), a storage device having a memory such as a read only memory (ROM) or a random access memory (RAM), and an input and output interface device.

The arithmetic processing device of the control unit 100 executes a computer program stored in the ROM on the RAM to generate a control signal for controlling the processing apparatus 1. The arithmetic processing device of the control unit 100 outputs the generated control signal to each of the components of the processing apparatus 1 via the input and output interface device.

The control unit 100 is connected to a display unit 101 (illustrated in FIG. 7) including a liquid crystal display device or the like that displays the state of the cleaning operation, an image, and the like, and an input unit (not illustrated) used when an operator registers processing conditions. The input unit includes at least one of a touch panel provided to the display unit 101, a keyboard, or the like.

### Cleaning Step

Next, the cleaning step 502 will be described. The cleaning step 502 is also a cleaning method for cleaning the workpiece 200. As illustrated in FIG. 3, the cleaning step 502 includes a first cleaning step 5021, a first rinsing step 5022, a conveyance step 5023, a second cleaning step 5024, a rinsing step 5025, and a drying step 5026.

### First Cleaning Step

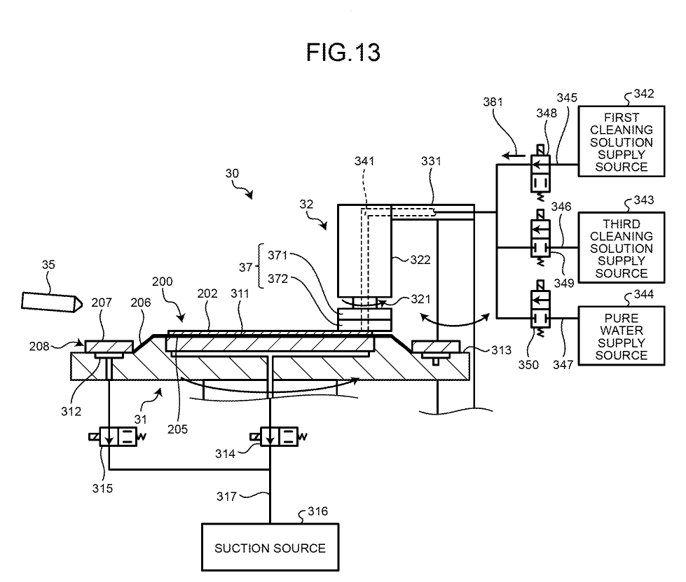

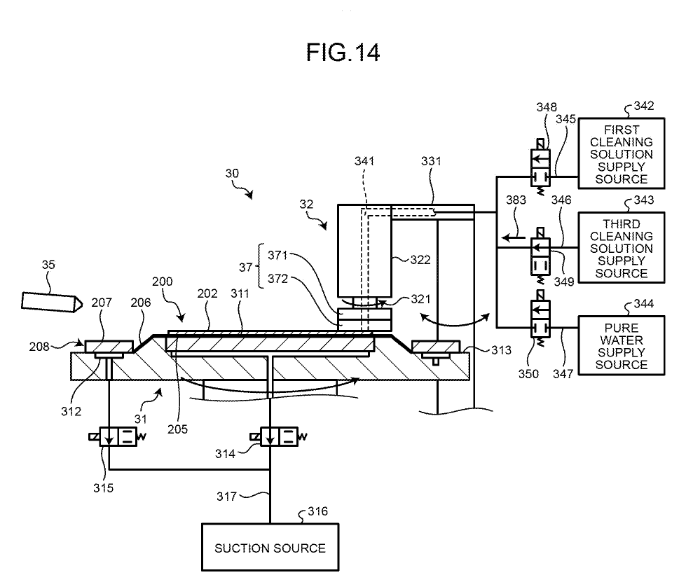

FIG. 13 is a side view schematically illustrating, in a partial cross section, a state in which the workpiece is cleaned by supplying the first cleaning solution at the first cleaning step of the working method illustrated in FIG. 3. FIG. 14 is a side view schematically illustrating, in a partial cross section, a state in which the workpiece is cleaned by supplying the third cleaning solution at the first cleaning step of the working method illustrated in FIG. 3.

The first cleaning step 5021 is a step of cleaning the workpiece 200 by pressing the workpiece 200 with the first cleaning member 37 under a predetermined load and moving the workpiece 200 and the first cleaning member 37 relative to each other, while supplying the first cleaning solution 381 to the workpiece 200. At the first cleaning step 5021 of the first embodiment, in the processing apparatus 1, the cassette 21 accommodating the workpiece 200 after the working step 501 is placed on one cassette placing table 20, and an empty cassette 21 is placed on the other cassette placing table 20.

At the first cleaning step 5021 of the first embodiment, the processing apparatus 1 starts the first cleaning step 5021 in a state where all the openings 6, 13, 15, and 17 are closed by the shutters 7, 14, 16, and 18, all the on-off valves 314, 315, 348, 349, 350, and 414 are closed, the rotation of the spinner tables 31 and 41 and the first cleaning member 37 is stopped, and the cleaning members 37 and 47 are retracted from the spinner tables 31 and 41. In the first embodiment, when the first cleaning step 5021 is started, the processing apparatus 1 moves the shutters 7 to open the openings 6, causes the loading/unloading unit 60 to take out one workpiece 200 before cleaning from the first cassette 21-1 to place the workpiece 200 onto the positioning members 19 on the shutter 18, and retracts the loading/unloading unit 60 to a loading/unloading unit standby area.

At the first cleaning step 5021 of the first embodiment, the processing apparatus 1 moves the shutter 7 on the cassette placing table 20 side, on which the first cassette 21-1 accommodating the workpiece 200 before cleaning is placed, to close the opening 6, and the conveyance unit 70 holds the frame 207 supporting the workpiece 200 on the positioning members 19, and moves the shutter 18 to open the opening 17. At the first cleaning step 5021 of the first embodiment, in the processing apparatus 1, the conveyance unit 70 places the workpiece 200 before cleaning on the holding surface 311 of the first spinner table 31 and places the frame 207 on the frame suction unit 313.

At the first cleaning step 5021 of the first embodiment, the processing apparatus 1 retracts the conveyance unit 70 from the first spinner table 31 and moves the shutter 18 to close the opening 17. At the first cleaning step 5021 of the first embodiment, the processing apparatus 1 opens the on-off valves 314 and 315 to suck and hold the workpiece 200 on the holding surface 311 of the first spinner table 31 and to suck and hold the frame 207 on the frame suction unit 313.

At the first cleaning step 5021 of the first embodiment, in the processing apparatus 1, as illustrated in FIG. 13, the first moving unit 33 rotates the first spinner table 31 about its axis while the on-off valve 348 is opened and the first cleaning solution 381 is supplied to the lower surface of the polishing pad 372, and the arm 331 is swung while the front surface 202 of the workpiece 200 is pressed with the lower surface of the polishing pad 372 under a predetermined load. At the first cleaning step 5021 of the first embodiment, in the processing apparatus 1, the predetermined load of pressing the front surface 202 of the workpiece 200 with the polishing pad 372 is, for example, equal to or larger than 0.8 Lbf/in2 (psi) and equal to or less than 1.2 Lbf/in2 (psi), and preferably equal to or less than 1.0 Lbf/in2 (psi).

As such, in the first embodiment, the predetermined load to press the front surface 202 of the workpiece 200 with the polishing pad 372 during the first cleaning step 5021 is generally weaker than the load (for example, 1.5 Lbf/in2 (psi)) in performing chemical mechanical polishing (CMP) on the workpiece 200. In the present invention, the predetermined load at the first cleaning step 5021 may be modified, or cleaning may be performed under the same predetermined load. At the first cleaning step 5021 of the first embodiment, the processing apparatus 1 sets the rotation speed of the first spinner table 31 to, for example, 300 min-1, the rotation speed of the first cleaning member 37 to 200 min-1, the swing speed of the arm 331 to, for example, 2°/sec, and the time for cleaning the front surface 202 of the workpiece 200 while supplying the first cleaning solution 381 to, for example, 30 seconds.

The workpiece 200 may have a metal portion such as a test element group (TEG) formed on the planned division line 203. When such a workpiece 200 is cut by the cutting blade 82, burr is formed at the edge of a cutting groove. However, at the first cleaning step 5021 of the first embodiment, the processing apparatus 1 slides the first cleaning member 37 on the front surface 202 while the front surface 202 is pressed with the polishing pad 372 of the first cleaning member 37 under a predetermined load, whereby the burr can be scraped off and removed.

At the first cleaning step 5021 of the first embodiment, as illustrated in FIG. 14, the processing apparatus 1 closes the on-off valve 348 while maintaining the rotational speed of the first spinner table 31 and the first cleaning member 37, opens the on-off valve 349, and cleans the front surface 202 of the workpiece 200 while supplying the third cleaning solution 383 to the lower surface of the polishing pad 372. At the first cleaning step 5021 of the first embodiment, the processing apparatus 1 sets the time for cleaning the front surface 202 of the workpiece 200 while supplying the third cleaning solution 383 to, for example, 30 seconds. At the first cleaning step 5021 of the first embodiment, the front surface 202 of the workpiece 200 may be cleaned by supplying only the first cleaning solution 381 without supplying the third cleaning solution 383. In this manner, the first cleaning step 5021 is performed with the workpiece 200 accommodated in the first cleaning chamber 8.

### First Rinsing Step

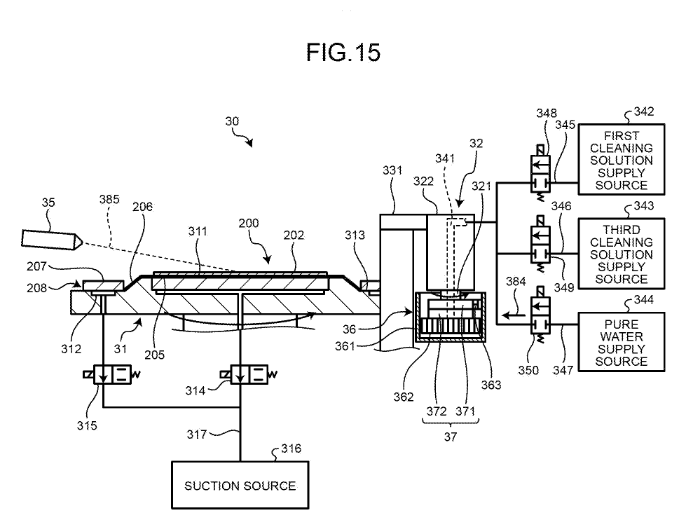

FIG. 15 is a side view schematically illustrating, in a partial cross section, the first rinsing step of the working method illustrated in FIG. 3. The first rinsing step 5022 is a step of supplying the rinse water 385 to the workpiece 200 to rinse the workpiece 200 after performing the first cleaning step 5021 and before performing the second cleaning step 5024.

At the first rinsing step 5022 of the first embodiment, as illustrated in FIG. 15, in the processing apparatus 1, the first moving unit 33 retracts the first cleaning member 37 from the workpiece 200 and accommodates the first cleaning member in the first cleaning member cleaner 36, closes the on-off valve 349, opens the on-off valve 350, and supplies the pure water 384 into the first cleaning member cleaner 36. At the first rinsing step 5022 of the first embodiment, the processing apparatus 1 supplies the rinse water 385 from the first rinse water supply nozzle 35 to the front surface 202 of the workpiece 200.

At the first rinsing step 5022 of the first embodiment, the processing apparatus 1 sets the rotation speed of the first spinner table 31 to, for example, 300 min-1 and supplies the rinse water 385 to the front surface 202 of the workpiece 200 for, for example, about 10 seconds. In the present invention, the first rinsing step 5022 may not be performed.

### Conveyance Step

The conveyance step 5023 is a step of, after the first cleaning step 5021 and before the second cleaning step 5024, supplying the rinse water 385 to the front surface 202 of the workpiece 200, and conveying the workpiece 200 from the first cleaning chamber 8 to the second cleaning chamber 9 while the rinse water 385 is supplied to the front surface 202. In the first embodiment, at the conveyance step 5023, the first moving unit 33 reduces the rotational speed of the first spinner table 31 to, for example, about 30 min-1, and supplies the rinse water 385 from the first rinse water supply nozzle 35 to the front surface 202 of the workpiece 200 for a predetermined time, and then the processing apparatus 1 stops the rotation of the first spinner table 31. By reducing the rotational speed of the first spinner table 31 in this manner, at the conveyance step 5023, the rinse water 385 is prevented from scattering from the front surface 202 of the workpiece 200, and the front surface 202 of the workpiece 200 is covered with the rinse water 385.

In the first embodiment, at the conveyance step 5023, the processing apparatus 1 closes the on-off valves 314 and 315 to stop suction holding of the workpiece 200 and the frame 207 on the first spinner table 31. At the conveyance step 5023 of the first embodiment, the processing apparatus 1 moves the shutter 18 to open the opening 17, and the conveyance unit 70 holds the frame 207, which supports the workpiece 200 on the first spinner table 31, and rises to a position above the middle plate 12. Then, the processing apparatus 1 moves the shutter 18 to close the opening 17. At the conveyance step 5023 of the first embodiment, the processing apparatus 1 moves the shutter 16 to open the opening 15, and the conveyance unit 70 conveys the frame 207, which supports the workpiece 200, to the second spinner table 41 and places the workpiece 200 on the second spinner table 41. At the conveyance step 5023, the conveyance unit 70 is retracted from the spinner tables 31 and 41, and the processing apparatus 1 moves the shutters 16 and 18 to close the openings 15 and 17, respectively.

In this manner, at the conveyance step 5023 of the first embodiment, after the first rinsing step 5022 or after the first cleaning step 5021 when not performing the first rinsing step 5022, the processing apparatus 1 conveys the workpiece to the second cleaning unit 40 with the workpiece 200 covered with the rinse water 385. When the front surface 202 of the workpiece 200 dries, foreign matter adheres to the front surface 202, making it difficult to remove the foreign matter even if cleaned later. However, in the first embodiment, since the workpiece 200 is conveyed with the front surface 202 covered with the rinse water 385, adhesion of foreign matter can be prevented.

At the conveyance step 5023, in the case where the conveyance unit 70 is provided with the rinse water supply unit 73, the processing apparatus 1 may supply the rinse water 385 from the rinse water supply unit 73 to the front surface 202 of the workpiece 200 during conveyance of the conveyance unit 70.

Furthermore, in the first embodiment, the first spinner table 31 of the first cleaning unit 30 is rotated about its axis by the first moving unit 33 except when the workpiece 200 is loaded and unloaded. In the first embodiment, the first cleaning member 37 of the first cleaning unit 30 is accommodated in the first cleaning member cleaner 36 except when the front surface 202 of the workpiece 200 is cleaned.

In the first embodiment, the first cleaning unit 30 opens the on-off valve 350 and constantly supplies the pure water 384 into the first cleaning member cleaner 36 as illustrated in FIG. 15 whenever neither the cleaning solutions 381 nor 383 is being supplied to the polishing pad 372 in the first cleaning member cleaner 36. With this, the processing apparatus 1 can prevent clogging of the polishing pad 372 of the first cleaning member 37. Furthermore, in the first embodiment, while the first cleaning member 37 is accommodated in the first cleaning member cleaner 36, the first cleaning unit 30 rotates the spindle 321, namely, the first cleaning member 37 about its axis at predetermined timing (for example, at predetermined time intervals), cleans the lower surface of the polishing pad 372 with the polishing surface cleaning brush 362, and cleans the outer peripheral surface of the platen 371 by the side surface cleaning brush 363.

### Second Cleaning Step

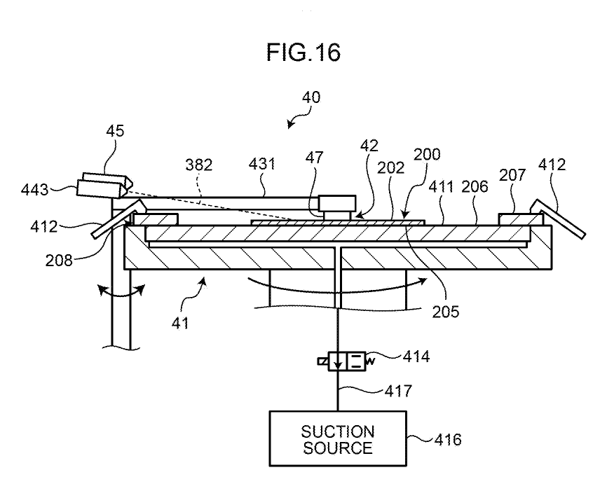

FIG. 16 is a side view schematically illustrating the second cleaning step of the working method illustrated in FIG. 3 in a partial cross section. The second cleaning step 5024 is a step of, after the first cleaning step 5021, cleaning the workpiece 200 by bringing the second cleaning member 47 into contact with the workpiece 200 and moving the workpiece 200 and the second cleaning member 47 relative to each other, while supplying the second cleaning solution 382 to the workpiece 200.

In the first embodiment, at the second cleaning step 5024, the processing apparatus 1 opens the on-off valve 414 to suck and hold the workpiece 200 on the holding surface 411 of the second spinner table 41. At the second cleaning step 5024 of the first embodiment, as illustrated in FIG. 16, the processing apparatus 1 causes the second moving unit 43 to rotate the second spinner table 41 about its axis while supplying the second cleaning solution 382 from the second cleaning solution supply nozzle 443 to the front surface 202 of the workpiece 200 held on the second spinner table 41, and causes the arm 431 to swing while the lower surface of the second cleaning member 47 is brought into contact with the front surface 202 of the workpiece 200.

At the second cleaning step 5024 of the first embodiment, the load applied by the second cleaning member 47 to press the front surface 202 of the workpiece 200 in the processing apparatus 1 is, for example, equal to or larger than 0.1 Lbf/in2 (psi) and equal to or less than 0.5 Lbf/in2 (psi). As such, the predetermined load at the first cleaning step 5021 is set to a value larger than the load applied to the workpiece 200 when the second cleaning member 47 comes into contact with the workpiece 200 at the second cleaning step 5024.

At the second cleaning step 5024 of the first embodiment, the processing apparatus 1 sets the rotation speed of the second spinner table 41 to, for example, 500 min-1, sets the swing speed of the arm 431 to, for example, 3°/sec, and sets the time for cleaning the front surface 202 of the workpiece 200 while supplying the second cleaning solution 382 to, for example, 60 seconds. Since the second cleaning solution 382 from the second cleaning solution supply nozzle 443 lands on a position avoiding the movement locus of the second cleaning member 47, the second cleaning solution lands on a position deviated from the center of the second spinner table 41. Therefore, with the rotation of the second spinner table 41, the second cleaning solution 382 flows between the second cleaning member 47 and the front surface 202 of the workpiece 200.

In this manner, the second cleaning step 5024 is performed with the workpiece 200 accommodated in the second cleaning chamber 9. In the first embodiment, the first cleaning step 5021 and the second cleaning step 5024 are performed with the workpiece 200 fixed onto the tape 206 and the outer periphery of the tape 206 fixed to the frame 207.

In the present invention, after the second cleaning step 5024, the front surface 202 of the workpiece 200 may be cleaned with ultrasonic water or mixed two-fluid of gas and liquid following the second cleaning step 5024.

### Rinsing Step

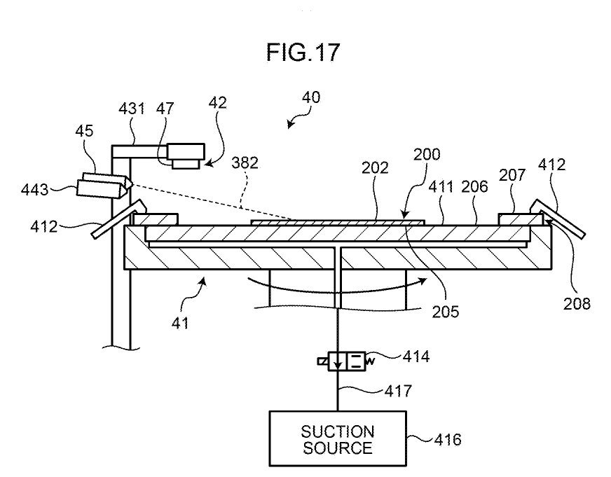

FIG. 17 is a side view schematically illustrating, in a partial cross section, the rinsing step of the working method illustrated in FIG. 3. The rinsing step 5025 is a step of supplying the rinse water 385 to the workpiece 200 to rinse the workpiece 200 after performing the second cleaning step 5024.

At the rinsing step 5025 of the first embodiment, as illustrated in FIG. 17, the processing apparatus 1 causes the second moving unit 43 to retract the second cleaning member 47 from the workpiece 200, and supplies the rinse water 385 from the second rinse water supply nozzle 45 to the front surface 202 of the workpiece 200. At the rinsing step 5025 of the first embodiment, the processing apparatus 1 sets the rotation speed of the second spinner table 41 to, for example, 500 min-1 and supplies the rinse water 385 to the front surface 202 of the workpiece 200 for, for example, about 90 sec.

### Drying Step

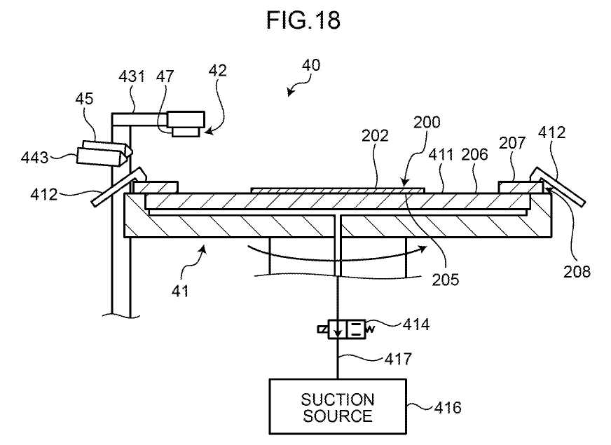

FIG. 18 is a side view schematically illustrating, in a partial cross section, the drying step of the working method illustrated in FIG. 3. The drying step 5026 is a step of drying the workpiece 200 after performing the rinsing step 5025.

At the drying step 5026 of the first embodiment, as illustrated in FIG. 18, the processing apparatus 1 stops the supply of the rinse water 385 from the second rinse water supply nozzle 45 and dries the workpiece 200 for about 120 seconds with the rotation speed of the second spinner table 41 set to, for example, 1500 min-1. After the workpiece 200 is dried, in the processing apparatus 1, the second moving unit 43 stops the rotation of the second spinner table 41, the shutter 14 is moved to open the opening 13, and the loading/unloading unit 60 unloads the workpiece 200 from the second spinner table 41 and accommodates the workpiece 200 in the second cassette 21-2. As such, in the first embodiment, in the processing apparatus 1, the shutters 7 are kept open from when the shutters 7 are opened for the loading/unloading unit 60 to take out the workpiece 200 from the first cassette 21-1. However, in the present invention, the shutters 7 may be opened only when the workpiece 200 is taken in and out and closed at other times. In the first embodiment, the shutters 7 are both opened and closed simultaneously. However, in the present invention, the shutters 7 may be opened and closed at different timings for the first cassette 21-1 and the second cassette 21-2; for example, and may, for example, be opened and closed only at the timing when the workpiece 200 is taken in or out.

In the first embodiment, the processing apparatus 1 sequentially performs the cleaning step 502 on workpieces 200 in the first cassette 21-1 one by one, and accommodates the workpieces 200 in the second cassette 21-2.

In the first embodiment, the processing apparatus 1 includes an exhaust port (not illustrated), to which an exhaust duct (not illustrated) is connected, and an air supply fan (not illustrated). With this, the processing apparatus 1 is controlled so that the pressure inside the processing apparatus 1 is lower than the atmospheric pressure outside the processing apparatus 1. As a result, particles including waste generated in the processing apparatus 1 and a chemical solution used in the processing apparatus 1 do not flow out of the processing apparatus 1.

In the first embodiment, with the housing 2 configured as described above in the processing apparatus 1, the space in the housing 2 is partitioned into the loading/unloading unit standby area 601 where the loading/unloading unit 60 waits, the first cleaning chamber 8, the second cleaning chamber 9, and the space 602 above the middle plate 12 as illustrated in FIGS. 8 and 9. In the first embodiment, in the processing apparatus 1, the loading/unloading unit standby area 601 where the loading/unloading unit 60 waits is set to have the highest positive pressure in the apparatus, and the second cleaning chamber 9 and the first cleaning chamber 8 are set to have pressures in descending order in the order mentioned. As a result, the processing apparatus 1 can prevent the chemical solution such as slurry that is used in the first cleaning chamber 8 from flowing out of the apparatus or into another area of the apparatus.

For example, it is difficult to completely remove the adhesive waste of the tape 206 and, for example, fine waste particle of 0.1 μm or less by normal cleaning (cleaning by spraying a cleaning fluid or a method of cleaning by abutting a brush). In cleaning methods such as the widely used spinner cleaning, in which a cleaning fluid flows over the object to be cleaned to wash away foreign matter, it is difficult to remove minute foreign matter adhering to the front side of the object. This is because the flow velocity of the cleaning fluid flowing over the object approaches zero as the cleaning fluid nears the surface of the object. That is, the force exerted by the cleaning fluid differs between the surface of the foreign matter adhering to the surface of the object and a position farther from the surface of the object, and the position farther from the surface of the object is washed away with greater force. The force exerted by the cleaning fluid differs between the side of the foreign matter adhering to the surface of the object being cleaned and the side farther from the surface; the side farther from the surface is washed away with greater force. For example, minute foreign matter particles as small as 0.1 μm or less receive a minute force, making it difficult to be removed. In the working method of the present application, a predetermined load is applied to the workpiece 200 by the first cleaning member 37 to scrape off the foreign matter, and thus the foreign matter can be effectively removed.

Meanwhile, foreign matter and particles not adhering to the workpiece 200 are taken into the cleaning solution supplied to the workpiece 200, then float in the cleaning solution, sink under their own weight, and re-adhere to the workpiece 200. In order to prevent adhesion to the workpiece 200, it is effective to continuously supply the cleaning solution and to perform cleaning for a long time.

However, if cleaning with a load is performed excessively, the workpiece 200 may be damaged. In particular, in a case where the workpiece 200 is a semiconductor device wafer and the devices 204 formed on the front surface 202 thereof are semiconductor devices, dishing or erosion may occur in wirings or electrode portions made of metal included in the devices 204.

In the working method according to the first embodiment described above, since the second cleaning step 5024 is performed after the first cleaning step 5021, it is possible to effectively remove foreign matter while keeping a duration of load-applied cleaning short.

In the working method according to the first embodiment, particularly in the case where the workpiece 200 is a semiconductor device wafer, burr of metal electrodes formed during the division of the workpiece 200 are also scraped off and removed at the first cleaning step 5021, thereby enabling the surface 202 to be formed flat after cleaning. Thus, the working method according to the first embodiment is suitable for hybrid bonding.

In the working method according to the first embodiment, at the first cleaning step 5021, cleaning is performed while a predetermined load is applied to the workpiece 200 with the first cleaning member 37, and at the second cleaning step 5024, the workpiece 200 is cleaned by the second cleaning member 47. Therefore, in the working method according to the first embodiment, at the first cleaning step 5021, cleaning is performed by applying a predetermined load larger than that at the second cleaning step 5024 to the workpiece 200, thereby achieving an effect of enabling further removal of foreign matter from the front surface 202 of the workpiece 200.

The present invention provides an effect of enabling further removal of foreign matter.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A cleaning method for cleaning an object to be cleaned, the method comprising:
a first cleaning step of cleaning the object by pressing the object with the first cleaning member under a predetermined load and moving the object and the first cleaning member relative to each other, while supplying a first cleaning solution to the object; and
a second cleaning step of cleaning the object after the first cleaning step by bringing a second cleaning member into contact with the object and moving the object and the second cleaning member relative to each other, while supplying a second cleaning solution to the object, wherein
the predetermined load at the first cleaning step is set to a value greater than a load applied to the object when the second cleaning member comes into contact with the object at the second cleaning step.

2. The cleaning method according to claim 1, wherein
the first cleaning member is disposed in a first cleaning chamber,
the first cleaning step is performed with the object accommodated in the first cleaning chamber,
the second cleaning member is disposed in a second cleaning chamber, and
the second cleaning step is performed with the object to be cleaned accommodated in the second cleaning chamber.

3. The cleaning method according to claim 2, further comprising, after the first cleaning step and before the second cleaning step,
a conveyance step of supplying rinse water to a surface to be cleaned of the object, and conveying the object from the first cleaning chamber to the second cleaning chamber while the rinse water is supplied to the surface to be cleaned.

4. The cleaning method according to claim 1, further comprising, after the second cleaning step,
a rinsing step of rinsing the object by supplying rinse water to the object.

5. The cleaning method according to claim 1, further comprising, after the first cleaning step and before the second cleaning step,
a first rinsing step of rinsing the object by supplying rinse water to the object.

6. The cleaning method according to claim 1, wherein
the first cleaning member has a pressing surface that presses the object, the pressing surface being smaller than the object, and
the second cleaning member has a contact surface that comes into contact with the object, the contact surface being smaller than the object.

7. The cleaning method according to claim 1, wherein the first cleaning step and the second cleaning step are performed with the object fixed onto a tape and with an outer periphery of the tape fixed to a frame.

8. A processing method for processing a workpiece, the method comprising:
a processing step of processing a workpiece;
a first cleaning step of cleaning the workpiece after the processing step by pressing the workpiece with the first cleaning member under a predetermined load and moving the workpiece and the first cleaning member relative to each other, while supplying a first cleaning solution to the workpiece; and
a second cleaning step of cleaning the workpiece after the first cleaning step by bringing a second cleaning member into contact with the workpiece and moving the workpiece and the second cleaning member relative to each other, while supplying a second cleaning solution to the workpiece, wherein
the predetermined load at the first cleaning step is set to a value greater than a load applied to the workpiece when the second cleaning member comes into contact with the workpiece at the second cleaning step.

9. A processing apparatus comprising:
a first cleaning solution supply unit that supplies a first cleaning solution to an object to be processed;
a first cleaning member that presses the object, to which the first cleaning solution has been supplied, under a predetermined load;
a first moving unit that moves the first cleaning member and the object relative to each other to clean the object with the first cleaning member;
a second cleaning solution supply unit that supplies a second cleaning solution to the object;
a second cleaning member that comes into contact with the object to which the second cleaning solution has been supplied; and
a second moving unit that moves the second cleaning member and the object relative to each other to clean the object with the second cleaning member, wherein
the predetermined load applied by the first cleaning member is set to a value greater than a load applied to the object when the second cleaning member comes into contact with the object.

10. The processing apparatus according to claim 9, further comprising:
a first cleaning chamber that accommodates the first cleaning member and is capable of accommodating the object; and
a second cleaning chamber that accommodates the second cleaning member and is capable of accommodating the object.

11. The processing apparatus according to claim 10, further comprising:
a conveyance unit that conveys the object from the first cleaning chamber to the second cleaning chamber, wherein
the conveyance unit includes:
a holder that holds the object; and
a rinse water supply unit that supplies rinse water to a surface to be processed of the object held by the holder.

12. The processing apparatus according to claim 9, wherein
the object is configured such that a workpiece is fixed onto a tape and an outer periphery of the tape is fixed to a frame,
the first cleaning solution supply unit and the second cleaning solution supply unit supply the first cleaning solution and the second cleaning solution, respectively, to at least the workpiece of the object, and
the first cleaning member and the second cleaning member each clean at least the workpiece of the object.

13. The cleaning method according to claim 4, further comprising, after the first cleaning step and before the second cleaning step,
a first rinsing step of rinsing the object by supplying rinse water to the object.
